(19) United States
(12) Patent Application Publication
(10) Pub. No.: US 2009/0065480 A1
(43) Pub. Date: Mar. 12, 2009

(54) Plasma Processing Apparatus

(76) Inventors: Tadahiro Ohmi, Miyagi (JP); Masaki Hirayama, Miyagi (JP)

Correspondence Address: FOLEY AND LARDNER LLP;SUITE 500, 3000 K STREET NW, WASHINGTON, DC, 20007, US

(21) Appl. No.: 11/990,309

(22) PCT Filed: Aug. 4, 2006
(86) PCT No.: PCT/JP2006/315464

§ 371 Date: Feb. 11, 2008

(30) Foreign Application Priority Data
Aug. 12, 2005 (JP) 2005-234878

(51) Int. Cl. B44C 1/22; C23F 1/08; B01J 19/08; C23C 16/54

(52) U.S. Cl. 216/69; 156/345.41; 118/723 FI; 156/345.33; 427/575

(57) ABSTRACT

Provided is a plasma processing apparatus which can perform uniform processing even when a substrate to be processed has a large area. The plasma processing apparatus propagates microwaves introduced into wave guide tubes to dielectric plates through slots, and performs plasma processing to the surface of the substrate by converting a gas supplied into a vacuum container into the plasma state. In the plasma processing apparatus, a plurality of waveguide tubes are arranged in parallel, a plurality of dielectric plates are arranged for each waveguide tube, and partitioning members formed of a conductor and grounded are arranged between the adjacent dielectric plates. The in-tube wavelength of the waveguide tube is adjusted to be an optimum value by vertically moving a plunger. Furthermore, unintended plasma generation is eliminated in a space between the dielectric plate and the adjacent member, and stable plasma can be efficiently generated. As a result, high-speed and uniform processings, such as etching, film-forming, cleaning, ashing, can be performed.

### TECHNICAL FIELD

This invention relates to a plasma processing apparatus and, in particular, relates to a plasma processing apparatus capable of uniformly processing a large-area substrate.

### BACKGROUND ART

A plasma processing method is a processing method that produces highly active ions and radicals (free radicals) by converting a specific gas into a plasma, thereby carrying out processing such as etching, film-forming, cleaning, or ashing on the surface of a processing substrate. A plasma processing apparatus is an apparatus for use in performing the plasma processing method. Energy for converting a gas into a plasma is often given by an electromagnetic wave. In the manufacturing process of semiconductors, solar cells, flat panel displays, or the like, use is made of a parallel-plate plasma processing apparatus using a high frequency of several MHz to several tens of MHz as an energy medium for converting a gas into a plasma, or an inductively coupled plasma processing apparatus. There is also known an electron cyclotron resonance plasma apparatus that uses both a microwave of 2.45 GHz and a DC magnetic field of 875 gauss to efficiently convert a gas into a plasma based on a cyclotron motion of electrons in a plasma and a microwave resonance phenomenon.

In recent years, it has been found that it is possible to efficiently generate a high-density plasma only with application of a microwave without using a resonance phenomenon, and attention has been paid to a plasma processing method or a plasma processing apparatus using such a plasma. As a plasma apparatus of this type, there is known, by Patent Document 1 (JP 2005-141941 A), an apparatus that propagates a microwave introduced into a rectangular waveguide to a dielectric plate through openings (called slots) of the waveguide, thereby converting a gas, introduced into a vacuum container, into a plasma. A plasma excited by a microwave according to such a technique has a high plasma density and a low electron temperature as compared with a plasma excited by a high frequency. Therefore, there is an advantage that it is possible to carry out high-speed and excellent processing that does not damage a substrate.

In a waveguide, a reflected wave generated by reflection due to slots and reflection at a short-circuit portion of an end surface of the waveguide and an incident wave interfere with each other to generate a standing wave. In order to excite a uniform plasma, it is necessary to uniformly and efficiently emit a microwave through all the slots. Thus, the slots are arranged at regular intervals at positions of antinodes of the standing wave. Given that “n” is a natural number and “λg” is a guide wavelength in a waveguide, the pitch of antinodes of a standing wave becomes “λg/2”. Therefore, if the pitch between the slots is set to “n×λg/2”, it is possible to generate a uniform plasma.

However, if the kind or pressure of gas introduced into a vacuum container, the microwave power, or the like is changed, the guide wavelength changes. If the guide wavelength deviates from an optimum value, the intensities of the microwave emitted through the respective slots are unequalized, so that the uniformity of the plasma is degraded. Therefore, there is a problem that the conditions for obtaining a uniform plasma are limited.

Generally, the actual guide wavelength does not completely agree with a design value due to variation in size and permittivity of respective portions of wave-guide paths, variation in impedance of contact portions, variation in frequency, and so on and varies among apparatuses. Particularly in large-size plasma processing apparatuses, waveguides are long and the number of slots per waveguide is large and, therefore, deviation in guide wavelength from an optimum value largely affects the uniformity of a plasma. Therefore, there is a problem that even if the conditions of use are limited, it is difficult to always generate a uniform plasma and, particularly, the properties vary among the apparatuses. Substrates of semiconductors, solar cells, flat panel displays, and so on are increasing in area more and more and plasma processing apparatuses are also increasing in size. It is obvious that these problems relating to the plasma uniformity will be actualized more and more in future.

In the plasma processing, the temperature of a dielectric plate increases (sometimes exceeding 400° C.) due to incidence of ions in a plasma, so that the dielectric plate expands. When the dielectric plate expands to contact an adjacent member, the expansion is suppressed and thus an excessive stress is applied to the dielectric plate, so that there occurs a case where the dielectric plate is broken. Therefore, a certain gap is necessary between the dielectric plate and the adjacent member. The expansion increases in amount as the dielectric plate increases in size. Thus, the gap should be set large for a large dielectric plate.

On the other hand, if this gap becomes greater than a certain degree (e.g. 0.1 mm or more), there arises a problem that unintended plasma generation occurs in the gap. When a plasma is generated in the gap, not only the plasma generation efficiency is lowered due to a waste of microwave energy, but also the plasma uniformity and stability are significantly impaired. Following the increase in area of the substrates, dielectric plates also increase in area. It is obvious that the problem relating to the generation of a plasma in a gap between a dielectric plate and an adjacent member will be actualized more and more.

In the plasma processing, the flow of a gas in a vacuum container affects the uniformity of the processing and, therefore, a method of introducing a gas into the vacuum container is important. Particularly in the film-forming process, uniform film formation cannot be carried out unless a gas necessary for the plasma processing is uniformly ejected over the entire surface of a processing substrate.

However, for example, in a plasma processing apparatus described in Patent Document 2 (JP H9-63793 A), it is configured that a gas is introduced from the periphery of a processing substrate, so that a gas stay portion is formed at a center portion of the processing substrate. Therefore, there is a problem that uniform processing cannot be carried out and thus it can be applied only to a limited use.

On the other hand, in an apparatus described in Patent Document 3 (JP 2001-49442 A), a dielectric plate is in the form of a shower plate having a large number of gas ejection holes, so that a gas can be uniformly ejected over the entire surface of a processing substrate. However, since the dielectric plate is exposed to a strong microwave in the plasma processing, there is a case where unintended plasma generation occurs in the gas ejection holes formed in the dielectric plate. In order to suppress the plasma generation in the gas ejection holes, it is required to reduce the diameter of each gas ejection hole. Under the actual conditions of use, it is required that, for example, the diameter be set to 0.1 mm or less. However, high-level technique is required for uniformly forming a large number of such small holes in a dielectric plate made of a hard material such as ceramic or quartz and thus the cost and time is needed. Further, there also arises a problem that a film adheres to the gas ejection holes to block them in the plasma processing.

### Patent Document 1: JP 2005-141941 A

### Patent Document 2: JP H9-63793 A

### Patent Document 3: JP 2001-49442 A

### DISCLOSURE OF THE INVENTION

### Problem to be Solved by the Invention

A problem to be solved is that uniform processing cannot be carried out if a processing substrate has an increased area.

### Means for Solving the Problem

In order to solve the above-mentioned problem, according to the present invention, there is provided a plasma processing apparatus comprising a container in which a plasma is excited, a microwave supply system adapted to supply a microwave necessary for exciting the plasma into the container, a wave-guide path connected to the microwave supply system and formed with a plurality of slots, and a dielectric plate adapted to propagate the microwave emitted through the slots to the plasma, the plasma processing apparatus comprising means for adjusting a wavelength of the microwave propagating in the wave-guide path, from the outside of the wave-guide path (claim 1).

Preferably, the plasma processing apparatus is configured to move part of a conductor wall forming the wave-guide path from the outside of the wave-guide path (claim 2). The wave-guide path may be a rectangular waveguide and the plasma processing apparatus may be configured to move at least part of an E-surface (narrow wall surface) guide wall of the waveguide from the outside of the waveguide (claim 3). The plasma processing apparatus may comprise a plurality of rods inserted into the wave-guide path and may be configured to move each rod from the outside of the wave-guide path (claim 4). The plasma processing apparatus may comprise a first dielectric member in the wave-guide path and may be configured to move the first dielectric member from the outside of the wave-guide path (claim 5). The plasma processing apparatus may be configured to adjust the wavelength by changing a frequency of the microwave supplied by the microwave supply system (claim 6).

According to the present invention, there is also provided a plasma processing apparatus comprising a container in which a plasma is excited, a gas supply system adapted to supply a gas into the container, a microwave supply system adapted to supply a microwave necessary for exciting the plasma into the container, one or more waveguides connected to the microwave supply system and formed with a plurality of slots, a plurality of dielectric plates adapted to propagate the microwave emitted through the slots to the plasma, and a stage disposed in the container for placing thereon a processing substrate, wherein a plurality of the dielectric plates are provided per the waveguide and a partition member made of a conductor at least partly is provided between the adjacent dielectric plates (claim 7).

Preferably, the plasma processing apparatus comprises the waveguides (claim 8). At least part of airtightness maintaining portions located between the inside and the outside of the container may be provided between a surface, on the side of the slots, of each dielectric plate and the container (claim 9). A pitch between the dielectric plates in a traveling direction of the microwave propagating in the waveguide and a pitch between the slots in the traveling direction may be substantially equal to each other (claim 10). The pitch between the slots in the traveling direction may be substantially equal to a natural number times “½” of a wavelength of the microwave propagating in the waveguide (claim 11). The pitch between the slots in the traveling direction may be substantially equal to “½” of the wavelength (claim 12). A second dielectric member may be provided on at least part of the inside of each slot (claim 13). A plurality of second dielectric members having different permittivities may be provided in at least part of each slot (claim 14). A third dielectric member may be provided on at least part of the inside of the waveguide (claim 15). The waveguide may be a rectangular waveguide and the slots may be formed in an H surface (wide wall surface) of the waveguide (claim 16). The waveguide may be a rectangular waveguide and the slots may be formed in an E surface (narrow wall surface) of the waveguide (claim 17). The plasma processing apparatus may have a function of adjusting a wavelength of the microwave propagating in the waveguide, from the outside of the waveguide (claim 18). The plasma processing apparatus may be configured to move part of a guide wall of the waveguide from the outside of the waveguide (claim 19). The plasma processing apparatus may comprise a plurality of rods inserted into the waveguide and may be configured to move each rod from the outside of the waveguide (claim 20). The plasma processing apparatus may comprise a first dielectric member in the waveguide and may be configured to move the first dielectric member from the outside of the waveguide (claim 21). A thickness of each dielectric plate may be set depending on a distance from the slot facing the dielectric plate (claim 22). A distance between the partition member and the stage may be set shorter than a distance between each dielectric plate and the stage (claim 23). The partition member may have a gas ejecting function for ejecting the gas introduced from the gas supply system into the container (claim 24). The partition member may comprise a plurality of gas ejection holes for ejecting the gas into the container (claim 25). The partition member may comprise a gas flow path for conducting the gas introduced from the gas supply system to the plurality of gas ejection holes (claim 26).

There is also provided a product manufacturing method of manufacturing a product by carrying out processing using the plasma processing apparatus described above (claim 27).

### EFFECT OF THE INVENTION

According to this invention, by providing means for adjusting a guide wavelength from the outside of a wave-guide path and by adjusting the guide wavelength of the wave-guide path by that means, the guide wavelength can always be maintained at an optimum value even if the conditions of use, such as the kind or pressure of gas or the microwave power, are changed. Therefore, it is possible to always generate a uniform plasma under the conditions of use over an extremely wide range. For example, it becomes possible to flexibly cope with even a process that is performed while continuously changing the conditions of use. Further, since the guide wavelength can be set to an optimum value even if there are various variations in the manufacture of plasma processing apparatuses, it is possible to easily obtain a uniform plasma even if a plasma processing apparatus has an increased size.

Further, according to this invention, by providing a plurality of waveguides and providing a plurality of dielectric plates for each waveguide, each dielectric plate is extremely reduced in size and thus the influence of thermal expansion of the dielectric plate is diminished and, therefore, gaps between the dielectric plates and adjacent members can be set small. Accordingly, even if a processing substrate has an increased area, there arises no such a problem that unintended plasma generation occurs in the gaps between the dielectric plates and the adjacent members.

Further, by providing a plurality of gas ejection holes in a partition member, the pitch between the gas ejection holes can be set small. Thus, a gas can be uniformly supplied over the entire surface of a processing substrate and, therefore, uniform processing with no unevenness is enabled. Further, since the partition member is made of a conductor and grounded, the microwave electric field is applied to the inside of the gas ejection holes. Therefore, the problem of generation of unintended plasma is not caused.

### BRIEF DESCRIPTION OF THE DRAWINGS

FIG. 1 is a diagram showing in section one embodiment among plasma processing apparatuses of this invention. (Embodiment 1)

FIG. 2 is a diagram showing a section taken along A-A in FIG. 1.

FIG. 3 is a diagram showing a section taken along B-B in FIG. 1.

FIG. 4 is a diagram showing the electron density distributions over a substrate in a direction perpendicular to the axis of a waveguide.

FIG. 5 is a diagram showing the plunger position h dependence of electron density distribution over a substrate in the waveguide axial direction.

FIG. 6 is a diagram showing the frequency f dependence of electron density distribution over a substrate in the waveguide axial direction.

FIG. 7 is a diagram showing a section of a gas ejection portion having a bolt with a gas hole.

FIG. 8 is a diagram showing a section of a gas ejection portion having a porous member.

FIG. 9 is a diagram showing in section one embodiment among plasma processing apparatuses of this invention. (Embodiment 2)

FIG. 10 is a diagram showing the in-slot dielectric thickness dependence of electron density distribution over a substrate in the waveguide axial direction. (solid line: in the case where the thicknesses of in-slot dielectrics 202 and 203 are set to 5 mm in all the slots; broken line: in the case where the thicknesses of in-slot dielectrics 202 and 203 are set to 4 mm and 6 mm, respectively, only in the slots at both ends and set to 5 mm in the other slots)

FIG. 11 is a diagram showing in section one embodiment among plasma processing apparatuses of this invention. (Embodiment 3)

FIG. 12 is a diagram showing a section taken along A-A in FIG. 11.

FIG. 13 is a diagram showing in section one embodiment among plasma processing apparatuses of this invention. (Embodiment 4)

FIG. 14 is a diagram showing in section one embodiment among plasma processing apparatuses of this invention. (Embodiment 5)

### BEST MODE FOR CARRYING OUT THE INVENTION

Hereinbelow, plasma processing apparatuses of this invention will be described with reference to the drawings. However, this invention is not limited to those embodiments.

### Embodiment 1

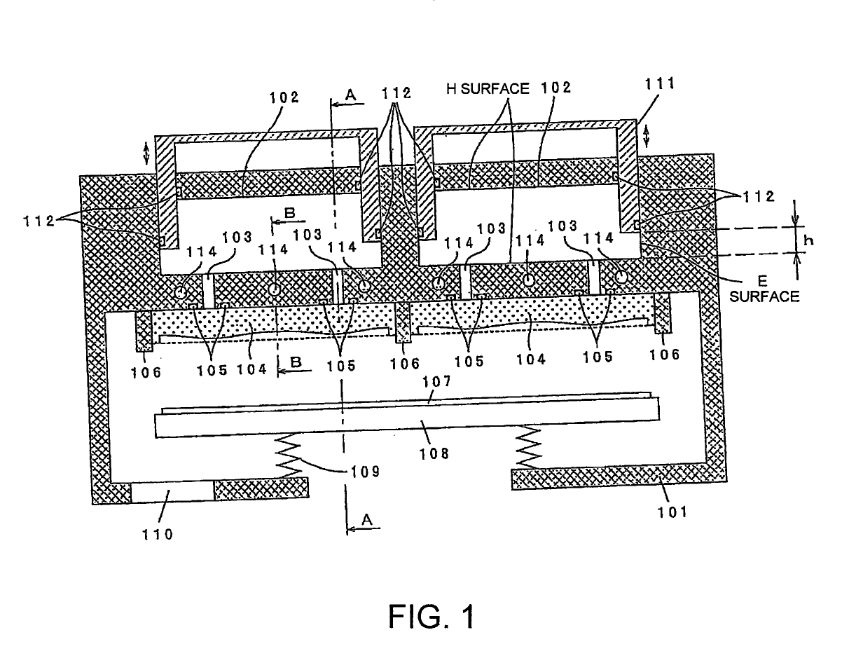

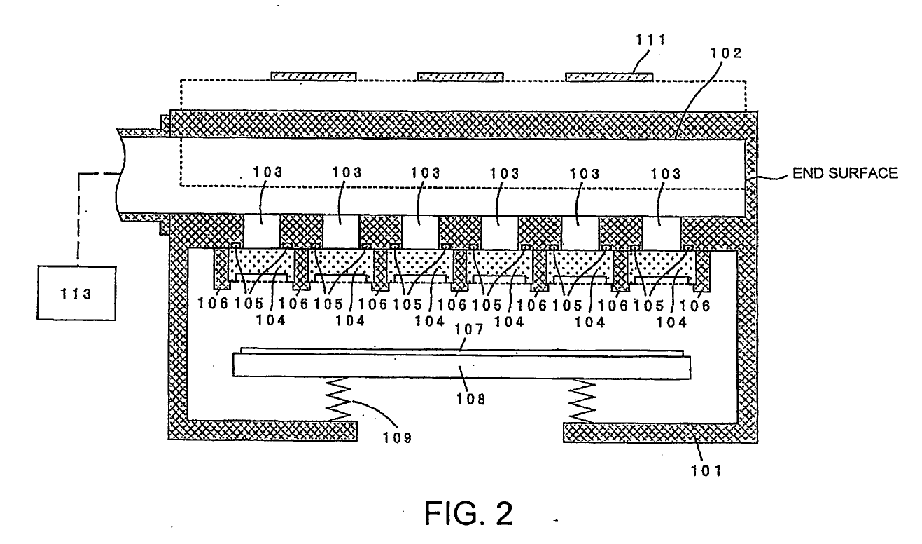

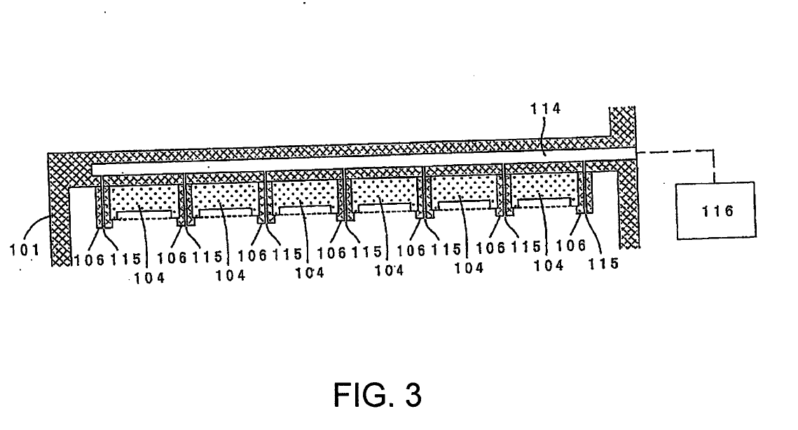

FIG. 1 is a sectional view showing the first embodiment among the plasma processing apparatuses of this invention. FIG. 2 is a sectional view taken along A-A in FIG. 1 and FIG. 3 is a sectional view taken along B-B in FIG. 1.

A vacuum container 101 is made of, for example, aluminum and is in a state of being grounded. A substrate 107 and a stage 108 for the substrate 107 are provided in the vacuum container 101. The substrate 107 is, for example, a glass substrate. A bellows 109 is provided between the stage 108 and the vacuum container 101, so that the stage 108 can be moved up and down by a non-illustrated elevator mechanism while maintaining airtightness. In the lower part of the vacuum container 101, there are provided exhaust ports 110 for exhausting gas in the vacuum container 101 by the use of a vacuum pump or the like provided outside the vacuum container 101.

Two rectangular waveguides 102 are disposed in parallel to each other, i.e. with their H surfaces (wide wall surfaces of the rectangular waveguides) being parallel to the substrate 107. The waveguides 102 each have one end forming a short-circuit surface and the other end to which a microwave supply system 113 is connected through a waveguide and a branch. The microwave supply system 113 comprises, for example, a magnetron, an isolator, an incidence/reflection power meter, and an automatic matching unit and is capable of generating a microwave with a frequency of 2.45 GHz and a maximum power of 2 kW.

A plurality of slots 103 are formed at regular intervals in two rows in a surface, on the side of the stage 108, of each waveguide 102. The inside of each waveguide 102 and the inside of each slot 103 are made hollow. On the surface of each waveguide 102 on the side of the stage 108, rectangular parallelepiped dielectric plates 104 are disposed such that each dielectric plate 104 lies over the slots 103 of the two rows. The dielectric plates 104 are made of quartz, but may be made of mullite, alumina, sapphire, yttria, aluminum nitride, silicon nitride, or the like.

O-rings 105 are disposed so as to surround the slots 103, respectively, thereby maintaining the airtightness of the vacuum container 101. The inner side of each O-ring 105, the inside of each slot 103, and the inside of each waveguide 102 are filled with the atmosphere.

A microwave generated by the microwave supply system 113 is introduced into the two waveguides 102 through the branches and then propagates in the waveguides 102 in a TE₁₀ mode. Part of the microwave propagating in the waveguides 102 is supplied to the dielectric plates 104 through the respective slots 103 and spreads over the dielectric plates 104 entirely. Electrons in a plasma are accelerated by a microwave electric field in the vicinity of each dielectric plate 104, so that the plasma is generated and maintained.

Although the microwave propagates in each dielectric plate 104, the intensity of the electric field tends to increase in the vicinity of each slot 103 and thus the plasma density tends to increase in the vicinity of each slot 103. In order to suppress this unevenness of the plasma density in a direction perpendicular to the axis of the waveguide, the thickness distribution of each dielectric plate 104 is optimized. As shown in FIG. 1, the thickness of each dielectric plate 104 is set greater in the vicinity of each slot 103 where the plasma density tends to increase, while, is set smaller at portions away from the slots 103. On the periphery of each dielectric plate 104, a sleeve-like flat portion is provided so as to prevent the high-density plasma from directly contacting a partition member 106.

Each dielectric plate 104 forms a wave-guide path for microwave having an upper surface and side surfaces surrounded by the metal walls and a lower surface by the plasma. In this embodiment, the plurality of dielectric plates 104 are provided for each waveguide 102 and the pitch between the dielectric plates 104 is set equal to the pitch between the slots 103. Therefore, the width of each dielectric plate 104 is set to be extremely narrow so that the microwave propagating in the dielectric plate 104 propagates in a mode similar to a single-mode rectangular waveguide. In this state, the microwave electric field mainly passes in the dielectric plate 104 at the thick portion thereof and thus a plasma is not so much excited, while, it also passes in a plasma at the thin portion thereof and thus the plasma is actively excited. In this manner, by optimizing the thickness distribution of the dielectric plate 104, it is possible to uniform the plasma density distribution in the dielectric plate 104.

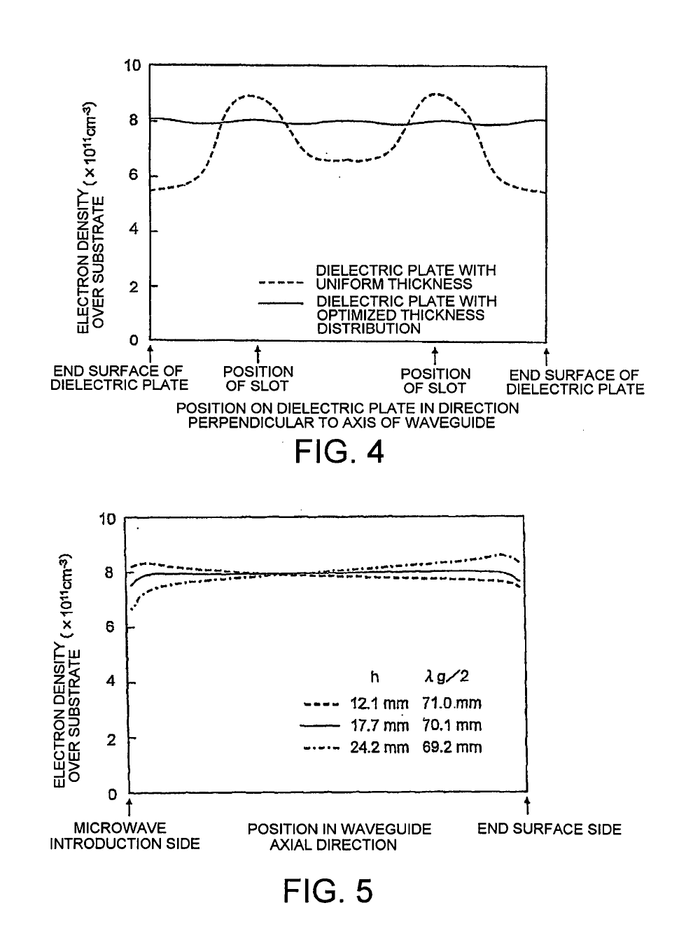

FIG. 4 shows the results of measuring the electron density distribution over the substrate 107 in the direction perpendicular to the axis of the waveguide. A broken line shows the results when dielectric plates each having a uniform thickness were used, while, a solid line shows the results when dielectric plates each having an optimized thickness distribution were used. “Ar” was used as a gas. The pressure was set to 100 Pa.

In the case of using the dielectric plates each having the uniform thickness, the electron density in the vicinity of each slot 103 is high, so that the plasma distribution in the direction perpendicular to the axis of the waveguide is extremely nonuniform. On the other hand, in the case of using the dielectric plates each having the optimized thickness distribution, the substantially uniform distribution is obtained. In this manner, the optimization of the thickness distribution of the dielectric plates 104 is quite effective for obtaining a uniform plasma.

In this embodiment, the thickness of each dielectric plate 104 is in the relationship of a monotonous decrease with respect to a distance from the slot 103. However, it is not necessarily the monotonous decrease. Further, although the thickness of each dielectric plate 104 is continuously changed in the direction perpendicular to the axis of the waveguide, it may be changed stepwise by arranging flat portions side by side. Further, in order to prevent plasma dense and sparse portions from moving in the direction perpendicular to the axis of the waveguide to thereby enhance the stability of a plasma, a protruding portion may be provided at a stepped portion where the thickness of the dielectric plate 104 changes.

The dielectric plates 104 are surrounded by and simultaneously held by the partition member 106 made of, for example, aluminum. Since the partition member 106 is made of a conductor and electrically grounded, the propagation of the microwave between the adjacent dielectric plates 104 is suppressed. Further, the distance between the partition member 106 and the stage 108 is set shorter than that between each dielectric plate 104 and the stage 108 to thereby cause the partition portions to protrude, so that the propagation of the microwave between the dielectric plates 104 is suppressed more reliably. Consequently, the manners of the microwave propagation in the dielectric plates 104 are determined independently of each other and thus there is obtained a plasma that is easily controllable and excellent in uniformity and stability.

In each waveguide 102, a reflected wave generated by reflection due to the slots 103 and reflection on an end surface and an incident wave interfere with each other to generate a standing wave. In order to equalize the intensities of the microwave emitted through the respective slots 103, it is required that the slots 103 be arranged at positions where the wall current flowing along the H surface becomes substantially maximum. That is, it is required that the pitch between the slots 103 in the waveguide axial direction and the distance from the end surface of the waveguide 102 to the closest slot be set to approximately “n×λg/2” (n is a natural number and λg is a guide wavelength). In this embodiment, n is set to “1”, but may be a natural number other than “1”.

The guide wavelength λg of the rectangular waveguide with the slots is given by the following formula (1).

$$\begin{matrix}[ Formula 1 ] & \\ λ g = K \frac{{λ}_{0}}{\sqrt{{ɛ}_{r} - {( {λ}_{0} / 2 a )}^{2}}} & ( 1 )\end{matrix}$$

Herein, “a” is a width of the H surface of the waveguide. “∈ᵣ” is a relative permittivity in the waveguide and, in this embodiment, is “1” because of being hollow. “λ₀” is a wavelength in a free space and is equal to “c/f” where c is a speed of light in a vacuum and f is a frequency of a microwave. In this embodiment, the frequency of the microwave is 2.45 GHz and thus the wavelength λ₀ in the free space is 122 mm. “K” is a wavelength reduction ratio which is “1” if there is no slot and which, if there is a slot, is a real number determined by an impedance of the slot. The wavelength reduction ratio K is a function of the permittivity, shape, and position of the slot 103, the permittivity and shape of the dielectric plate 104, the permittivity (also including a complex part) of a plasma, and so on. Among them, the permittivity of the plasma is determined by the density and temperature of electrons in the plasma, the kind and pressure of gas, and so on.

Therefore, if the kind or pressure of gas supplied to the vacuum container 101, the microwave power, or the like is changed, the wavelength reduction ratio K changes and thus the guide wavelength λg also changes. If the guide wavelength deviates from an optimum value, the intensities of the microwave emitted through the respective slots 103 are unequalized, so that the uniformity of the plasma is degraded. Therefore, it is preferable that there be provided a function of adjusting the guide wavelength so as to maintain the guide wavelength constant even if various conditions are changed.

Generally, the actual guide wavelength does not completely agree with a design value due to variation in size and permittivity of respective portions of wave-guide paths, variation in impedance of contact portions, variation in frequency, and so on and varies among apparatuses. Particularly in large-size plasma processing apparatuses, waveguides are long and the number of slots per waveguide is large and, therefore, deviation in guide wavelength from an optimum value largely affects the uniformity of a plasma. Even if the conditions of use are limited and the permittivity of a plasma is constant, it is preferable that there be provided a function of correcting a deviation in guide wavelength.

According to the foregoing formula (1), it is seen that the guide wavelength λg is a function of the width a of the H surface, the relative permittivity ∈ᵣ in the waveguide, and the frequency f of the microwave. That is, the guide wavelength λg can be adjusted by changing these values.

In this embodiment, a plunger 111 is provided so as to be vertically movable along inner E surfaces of each waveguide 102 (narrow wall surfaces of each rectangular waveguide). By vertically moving the plunger 111 to effectively change the width a of the H surface of the waveguide 102, the guide wavelength λg can be adjusted. For example, when the plunger 111 is moved upward, the width a of the H surface effectively increases and thus the guide wavelength λg decreases.

Shield spirals 112 are provided between the plunger 111 and the waveguide 102, so that the discharge does not occur between them and thus the microwave current flowing along the wall surfaces surely flows even at sliding portions.

The microwave propagating in each waveguide 102 propagates while emitting energy through the slots 103 and thus is gradually attenuated as it approaches the end surface. Therefore, if “λg/2” completely agrees with the pitch between the slots 103, there is a case where the intensity of the microwave emitted through each slot 103 decreases on the side of the end surface depending on the conditions. In such a case, the position of the plunger 111 is adjusted to set “λg/2” to be slightly greater or slightly smaller than the pitch between the slots 103, thereby reducing the intensity of the microwave emitted through each slot 103 on the microwave introduction side. As a result, it is possible to obtain excellent uniformity on the whole. In this manner, in this embodiment, it is possible to always generate a uniform plasma under the conditions of use over an extremely wide range by providing the function of adjusting the guide wavelength.

Using the plasma processing apparatus of this invention, examination was made on how the plasma distribution changes when a plunger position h (see FIG. 1) representing a distance between the surface, where the slots 103 are present, of each waveguide 102 and the bottom end of the plunger 111 is changed. FIG. 5 shows the electron density distribution over a substrate in the waveguide axial direction. The pitch between the slots 103 was set to 71.0 mm. An introduced gas was “Ar”, the gas flow rate was 700 sccm, and the pressure was 100 Pa.

When the plunger position h is set to 12.1 mm (see a broken line), “λg/2” becomes 71.0 mm equal to the pitch between the slots 103. In this event, the electron density over the substrate is high on the microwave introduction side and is low on the end surface side. Then, when the plunger position h is set to 17.7 mm (see a solid line), “λg/2” becomes 70.1 mm somewhat shorter than the pitch between the slots 103. In this event, the electron density over the substrate is substantially uniform. Then, when the plunger position h is set to 24.2 mm (see a chain line), “λg/2” is further shortened to 69.2 mm. In this event, the electron density over the substrate is low on the microwave introduction side and is high on the end surface side. In this manner, it is seen that the plasma distribution in the waveguide axial direction changes depending on the plunger position h and that the uniform plasma is obtained by changing the plunger position h to optimize the guide wavelength λg.

Table 1 shows the results of examining how the optimum value of the plunger position h changes when an introducing gas and its pressure are changed. In the case of an “Ar” gas, a flow rate of 700 sccm, and a pressure of 100 Pa, the most uniform plasma was obtained when the plunger position h was 17.7 mm and “λg/2” was 70.1 mm as described above. Then, when the pressure was lowered to 10 Pa without changing the plunger position h, the wavelength reduction ratio K was reduced to shorten the guide wavelength λg, so that the plasma uniformity was degraded. The plunger position h was reduced to 15.1 mm to effectively decrease the width a of the H surface to thereby return the guide wavelength λg to 70.1 mm being the optimum value, so that a uniform plasma was again obtained.

TABLE 1

| | |
|---|---|
| Condition | Optimum Value of |

| Kind of Gas: Flow Rate | | Gas Pressure | Plunger Position h |
|---|---|---|---|
| Ar: | 700 sccm | 100 Pa | 17.7 mm |
| Ar: | 700 sccm | 10 Pa | 15.1 mm |
| Ar: | 600 sccm | 10 Pa | 24.9 mm |
| O₂: | 50 sccm | | |
| Ar: | 600 sccm | 10 Pa | 27.4 mm |
| SiH₄: | 100 sccm | | |

The same experiments were performed using a mixed gas of “Ar” and “O₂” and a mixed gas of “Ar” and “SiH₄” and, as a result, it became clear that the optimum value of the plunger position h for obtaining a uniform plasma differs depending on the conditions. This is because the permittivity of a plasma differs depending on the conditions. In this manner, it was demonstrated that a uniform plasma can always be obtained by changing the plunger position h to adjust the wavelength λg even if the conditions of use are changed.

As shown in FIG. 3, the partition member 106 is formed with a plurality of gas ejection holes 115 for ejecting a gas into the vacuum container 101. The gas ejection holes 115 communicate with gas flow paths 114. In this embodiment, the six gas flow paths 114 are arranged parallel to the waveguides 102. The gas supplied from a gas supply system 116 is divided into six routes and then led to the respective gas flow paths 114 so as to be uniformly ejected from the plurality of gas ejection holes 115.

According to this embodiment, by providing the plurality of dielectric plates 104 for each waveguide 102 and setting the pitch between the dielectric plates 104 to be equal to the pitch between the slots 103, each dielectric plate is extremely reduced in size and thus the influence of thermal expansion of the dielectric plate is diminished. Therefore, gaps between the dielectric plates 104 and the adjacent members can be set small. Accordingly, even if a substrate has an increased area, a plasma is not generated in any of the gaps between the dielectric plates and the adjacent members, so that a uniform and stable plasma can be efficiently produced.

Further, by providing the plurality of gas ejection holes 115 in the partition member 106, the pitch between the gas ejection holes can be set small. As a result, the gas can be supplied substantially uniformly over the entire surface of the substrate 107 and, therefore, even if the distance between each dielectric plate 104 and the substrate 107 is shortened, uniform processing with minimized unevenness can be carried out. Further, since the partition member 106 is made of the conductor and grounded, the microwave electric field is applied to the inside of each gas ejection hole so as to avoid the problem of generation of a plasma in the inside thereof.

Further, by providing the airtightness maintaining portions between the surface, on the side of the slots 103, of each dielectric plate 104 and the vacuum container 101, the area of the dielectric plate 104 in contact with the atmosphere is reduced so that a force exerted on the dielectric plate 104 due to the atmospheric pressure is decreased and, therefore, the required strength of the holding portion for the dielectric plate 104 is lowered. Accordingly, the width of the partition member 106 having the function of holding the dielectric plates 104 can be reduced. As a result, the lowering of the plasma density in the vicinity of the partition member 106 can be suppressed to thereby improve the uniformity of a plasma.

In this manner, even if the substrate has the increased area so that the plasma generating region is expanded, it is possible to efficiently generate a uniform and stable plasma under the conditions of use over the wide range. Further, since the gas required for the plasma processing is supplied substantially uniformly over the entire surface of the substrate, the uniform processing can be carried out even if the distance between each dielectric plate 104 and the substrate 107 is shortened. As a result, this apparatus is well adapted for wide use and is capable of performing uniform, high-speed, and high-performance processing.

In the plasma processing apparatus of this invention, the plasma excitation frequency is high as compared with a parallel-plate plasma processing apparatus using a high frequency for plasma excitation, or an inductively coupled plasma processing apparatus, and thus there is obtained a plasma with a low electron temperature and a high density. For example, the electron temperature is about 3 eV to 10 eV and the electron density is about 10¹⁰ to 10¹¹ cm⁻³ in the conventional parallel plasma processing apparatus, while, the electron temperature is about 0.3 eV to 3 eV and the electron density is about 10¹¹ to 10¹³ cm⁻³ in the plasma processing apparatus of this invention. Accordingly, there is an advantage that it is possible to carry out high-speed and excellent processing that does not damage a substrate.

The plasma processing apparatus of this invention was applied to part of the processing in the organic EL display manufacturing processes. The applied processing is film-forming of a silicon nitride film by a plasma chemical vapor deposition method. A mixed gas of “Ar, SiH₄, and NH₃” was supplied from the gas supply system 116, introduced into the vacuum container 101 from the gas ejection holes 115 through the gas flow paths 114, and exhausted through the exhaust ports 110 using the vacuum pump. The flow rates of the respective gases were set to 400 sccm, 30 sccm, and 120 sccm, respectively. A glass substrate was used as the substrate 107. The substrate temperature was set to 300° C.

A silicon nitride film is used as a gate insulating film, an interlayer insulating film, or a protective film, wherein an increase in withstand voltage, a reduction in leakage current, and an increase in film-forming speed are required. With respect to a silicon nitride film formed by the conventional parallel-plate plasma processing apparatus, the withstand voltage was, for example, 5.4 MV/cm, the leakage current was 2.4×10⁻⁶ A/cm⁻², and the film forming speed was 110 nm/min. On the other hand, with respect to a thin film formed by the plasma processing apparatus of this invention, the withstand voltage was, for example, 11.8 MV/cm, the leakage current was 1.6×10⁻⁸ A/cm⁻², and the film-forming speed was 280 nm/min. In this manner, it is possible to form at high speed the silicon nitride film having the excellent properties as compared with the conventional plasma processing apparatus. Further, the uniformity was also largely improved.

In this embodiment, each dielectric plate 104 is rectangular. However, it may be cylindrical or polygonal. The thickness of each dielectric plate 104 may be uniform. The partition member 106 and the vacuum container 101 may be integral with each other or may be covered with an insulator or the like. The partition portions are not necessarily provided with the level difference. Each waveguide 102 may be a ridge waveguide, a circular waveguide, or the like. The number of the waveguides 102 may be other than two, the number of the slots 103 per waveguide may be other than twelve, or the number of the gas flow paths 114 may be other than six. It may be configured that there are provided a plurality of systems each including a gas supply system 116, gas flow paths 114, and gas ejection holes 115, thereby supplying different gases, respectively. The slots 103 are arranged at the pitch of “λg/2” in two rows in each waveguide 102, but may be arranged in a single row. Further, the slots in one row and the other row may be arranged in zigzag.

In this embodiment, the movable plunger 111 is provided and the guide wavelength is adjusted by changing the position of the plunger. However, the guide wavelength may be adjusted by changing the frequency f of a microwave generated by the microwave supply system 113. In this case, the movable plunger 111 is unnecessary.

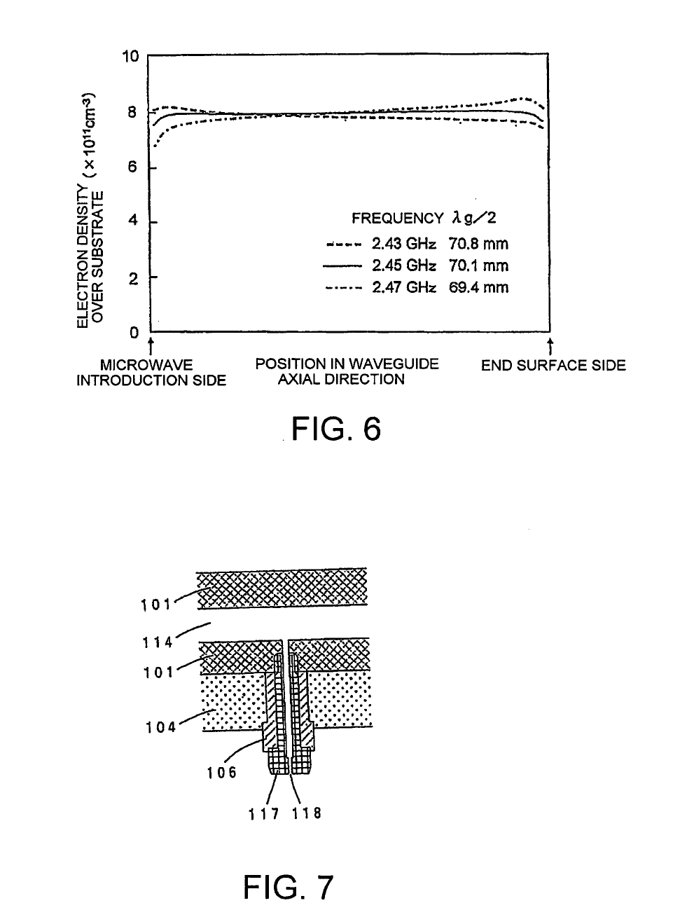

Using the plasma processing apparatus of this invention, examination was made on how the plasma distribution changes when the frequency f of the microwave is changed. FIG. 6 shows the electron density distribution over a substrate in the waveguide axial direction. The plunger position h was fixed to 17.7 mm. The pitch between the slots 103 was set to 71.0 mm. An introduced gas was “Ar”, the gas flow rate was 700 sccm, and the pressure was 100 Pa.

When the frequency of a microwave generated by the microwave supply system 113 is set to 2.43 GHz lower than the standard frequency by 0.02 GHz (see a broken line), “λg/2” becomes 70.8 mm. In this event, the electron density over the substrate is high on the microwave introduction side and is low on the end surface side. Then, when it is set to 2.45 GHz being the standard frequency (see a solid line), “λg/2” is somewhat shortened to 70.1 mm. In this event, the electron density over the substrate is substantially uniform. Then, when it is set to 2.47 GHz higher than the standard frequency by 0.02 GHz (see a chain line), “λg/2” is further shortened to 69.4 mm. In this event, the electron density over the substrate is low on the microwave introduction side and is high on the end surface side. In this manner, it is seen that the plasma distribution in the waveguide axial direction changes depending on the frequency of the microwave and that the uniform plasma is obtained by changing the frequency to optimize the guide wavelength λg.

FIG. 7 is a sectional view showing another mode of a gas ejection portion. Gas-hole bolts 117 are each formed with a gas ejection hole 118. A partition member 106 is fixed to a vacuum container 101 by the plurality of gas-hole bolts 117. The respective gas ejection holes 118 communicate with gas flow paths 114, so that a gas introduced into the gas flow paths 114 is ejected into the vacuum container 101 through the plurality of gas ejection holes 118. Since the gas-hole bolts 117 serve both to hold the partition member 106 and dielectric plates 104 and to eject the gas, the structure can be simplified.

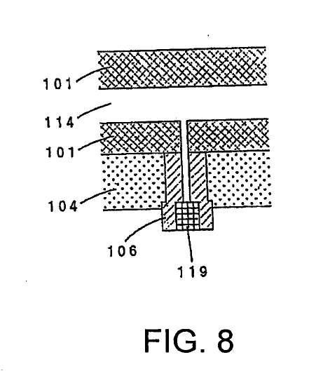

FIG. 8 is a longitudinal sectional view showing still another mode of a gas ejection portion. A partition member 106 is provided with porous members 119 made of, for example, alumina. A gas introduced to the porous members 119 through gas flow paths 114 passes through the inside of the porous members 119 so as to be ejected into a vacuum container 101. The gas can be ejected more uniformly as compared with the ejection through the gas ejection holes.

### Embodiment 2

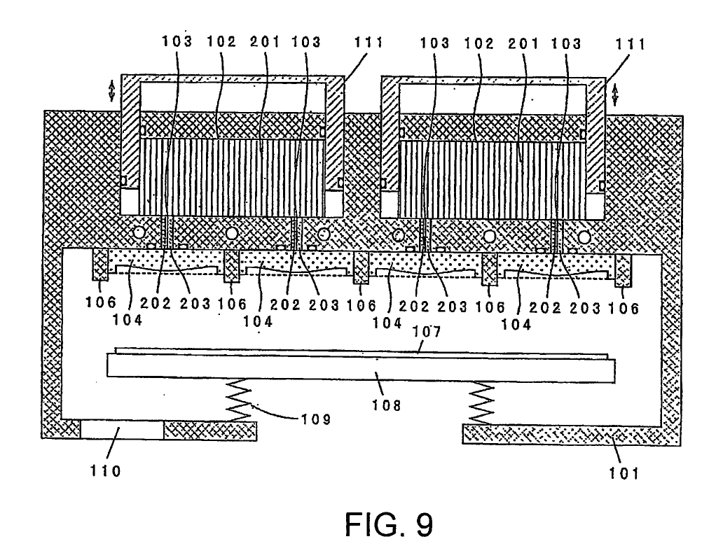

FIG. 9 is a sectional view showing the second embodiment among the plasma processing apparatuses of this invention. Herein, only what is different from the first embodiment will be described.

On the surface of each waveguide 102 on the side of a stage 108, rectangular parallelepiped dielectric plates 104 are disposed in one-to-one correspondence with slots 103. It may be configured that each dielectric plate 104 may be arranged so as to lie over the plurality of waveguides 102.

An in-waveguide dielectric 201 is provided in each waveguide 102. The in-waveguide dielectric 201 is made of a fluororesin having a relative permittivity of 2.1, but may be made of quartz, mullite, alumina, sapphire, yttria, aluminum nitride, silicon nitride, or the like. If the dielectric is inserted in the waveguide as described above, the size of a waveguide section and the guide wavelength λg are reduced. Given that the relative permittivity of an in-waveguide dielectric is “∈ᵣ”, the size of a waveguide section and the guide wavelength λg become “1/∈ᵣ^{1/2}” times as compared with the case of being hollow. By providing the in-waveguide dielectric 201 in each waveguide 102, the section size of each waveguide 102 is decreased and thus the apparatus can be reduced in size. Further, since the pitch between the slots 103 is reduced, the pitch between gas ejection holes is reduced and therefore a gas can be ejected more uniformly.

Flat plate-like in-slot dielectrics 202 and 203 are provided in each slot 103. The in-slot dielectrics 202 and 203 have different permittivities. For example, the in-slot dielectric 202 is made of a fluororesin having a relative permittivity of 2.1 and the in-slot dielectric 203 is made of quartz having a relative permittivity of 3.8. The in-slot dielectrics 202 and 203 may each be made of mullite, alumina, sapphire, yttria, aluminum nitride, silicon nitride, or the like.

If a dielectric is inserted in the slot 103 as described above, the intensity of a microwave emitted from the slot 103 changes. Accordingly, based on the permittivity of the in-slot dielectric, it is possible to control a plasma distribution by changing the intensity of a microwave emitted from the slots 103. Practically, it is difficult to continuously change the permittivity. Thus, in this embodiment, the intensity of a microwave emitted from the slots 103 is controlled by inserting two dielectrics having different permittivities into each slot 103 and changing the thickness thereof to change the effective permittivity in each slot.

In the plasma processing apparatus, the plasma density tends to be lower at the periphery of a substrate. Therefore, if the intensity of a microwave emitted from the slots at the periphery is set greater than that at the other portions, a uniform plasma tends to be obtained. In this embodiment, the thicknesses of the in-slot dielectrics 202 and 203 are set to 4 mm and 6 mm, respectively, in the slots 103 at both ends of each waveguide 102 and are both set to 5 mm in the other slots.

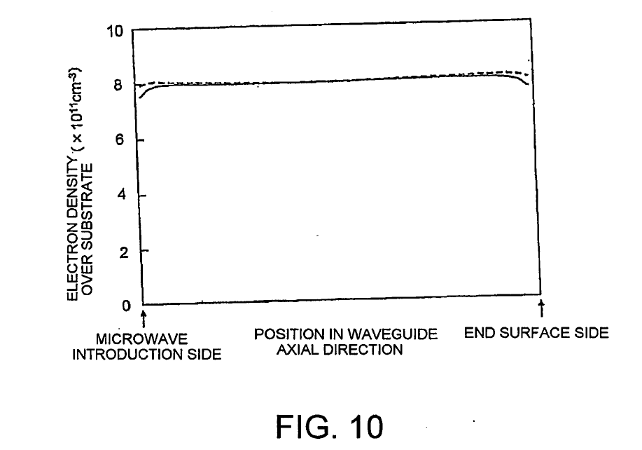

FIG. 10 shows the results of examining, using the plasma processing apparatus of this invention, how the electron density distribution over a substrate in the waveguide axial direction changes when the thicknesses of the in-slot dielectrics 202 and 203 are changed. An introduced gas was “Ar”, the gas flow rate was 700 sccm, and the pressure was 100 Pa.

It is seen that when the thicknesses of the in-slot dielectrics 202 and 203 are set to 5 mm in all the slots 103 (solid line), the electron density is lowered at both ends of the substrate. On the other hand, it is seen that when the thicknesses of the in-slot dielectrics 202 and 203 are set to 4 mm and 6 mm, respectively, only in the slots 103 at both ends (broken line), the lowering of the electron density is suppressed at both ends of the substrate so that a substantially uniform distribution is achieved. This is because, by setting the thickness of the in-slot dielectric 203 to be larger than that of the in-slot dielectric 202 in the slots 103 at both ends, the intensity of a microwave emitted from the slots 103 at both ends becomes greater than that from the other slots. In this manner, by changing the respective thicknesses of the in-slot dielectrics 202 and 203, the plasma distribution in the waveguide axial direction can be finely optimized.

In this embodiment, the in-slot dielectrics are divided into two in the left-right direction in FIG. 9. However, the in-slot dielectrics may be divided into other than two. Further, the in-slot dielectrics may be divided in the vertical direction in FIG. 9 or may be divided in a direction perpendicular to the drawing sheet.

### Embodiment 3

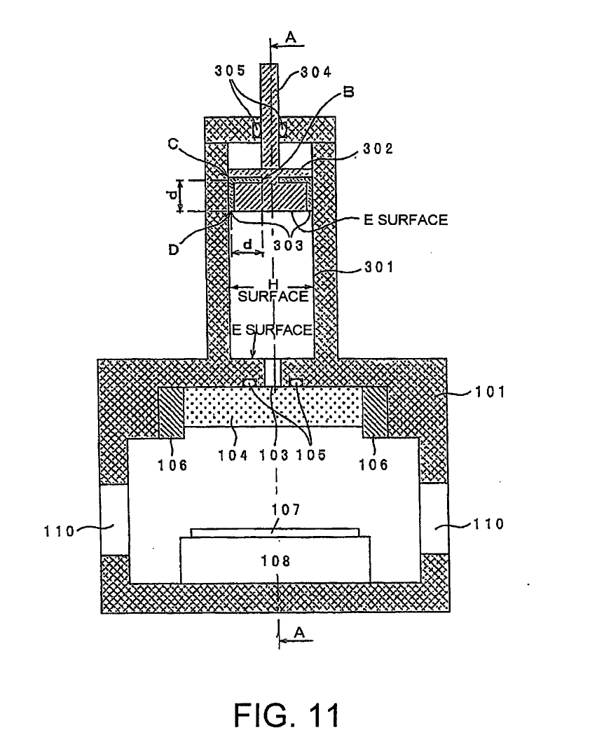

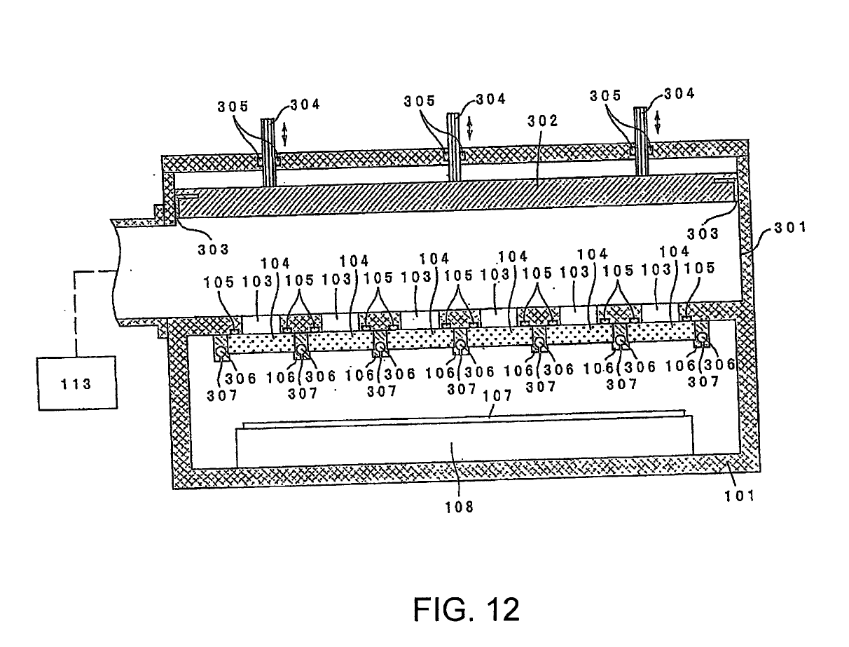

FIG. 11 is a sectional view showing the third embodiment among the plasma processing apparatuses of this invention. FIG. 12 is a sectional view taken along A-A in FIG. 11. Herein, only what is different from the first embodiment will be described.

A single rectangular waveguide 301 is disposed with its E surfaces (narrow wall surfaces of the rectangular waveguide) being parallel to a substrate 107. The waveguide 301 has one end forming a short-circuit surface and the other end to which a microwave supply system 113 is connected. In this embodiment, since an elongated plasma can be produced, it is suitable for the case where plasma processing is carried out for an elongated member or the case where plasma processing is carried out while moving a large-area substrate in a direction perpendicular to the axis of the waveguide.

A plurality of slots 103 are formed at regular intervals in a surface, on the side of a stage 108, of the waveguide 301. On the surface of the waveguide 301 on the side of the stage 108, rectangular parallelepiped dielectric plates 104 are disposed in one-to-one correspondence with the slots 103. It is required that the pitch between the slots 103 in the waveguide axial direction and the distance from the end surface of the waveguide 301 to the closest slot be set to approximately “n×λg/2” (n is a natural number). In this embodiment, n is set to “1”, but may be a natural number other than “1”.

In this embodiment, there is provided a vertically movable plunger 302 forming the E surface of the waveguide 301. Support rods 304 made of, for example, a stainless steel are fixed to the plunger 302. By vertically moving the plunger 302 along with the support rods 304 from the outside of the waveguide 301 to change the width of H surfaces of the waveguide 301, the guide wavelength can be adjusted. For example, when the plunger 302 is moved upward, the width of the H surfaces increases and thus the guide wavelength decreases (see the foregoing formula (1)). A plurality of plungers 302 may be arranged side by side in the waveguide axial direction. In this case, by changing the width of the H surfaces per plunger 302, the guide wavelength can be adjusted more precisely. In this embodiment, it is possible to always generate a uniform plasma under the conditions of use over an extremely wide range by providing the function of adjusting the guide wavelength.

The plunger 302 is provided with a choke dielectric 303. The choke dielectric 303 is made of alumina having a relative permittivity of 9.4, but may be made of a fluororesin, quartz, mullite, sapphire, yttria, aluminum nitride, silicon nitride, or the like or may be hollow. The length of a portion d in FIG. 11 is set to “¼” of a wavelength of a microwave in the choke dielectric 303, i.e. “λ₀/(4×∈ᵣ^{1/2})”. Herein, “λ₀” is a wavelength, in a free space, of a microwave generated by the microwave supply system 113 and “∈ᵣ” is a relative permittivity of the choke dielectric 303.

Such a structure is called a choke structure and used in a flange of a waveguide, a waveguide sliding portion of a matching unit, or the like.

Next, the operating principle of the choke structure will be described.

The choke dielectric 303 portion operates as a wave-guide path with shorted terminal faces for a microwave, wherein a standing wave is produced due to interference between an incident wave and a reflected wave. In FIG. 11, a portion B serves as a short-circuit surface, wherein an electric field in the choke dielectric 303 is “zero” and a current flowing on a wall surface is maximum. On the other hand, at a portion C away from the portion B by the “¼” wavelength, an electric field in the choke dielectric 303 is maximum and a current flowing on a wall surface is “zero”. A portion D away from the “½” wavelength from the portion B serves as an equivalent short-circuit surface, wherein an electric field in the choke dielectric 303 is “zero” and a current flowing on a wall surface is maximum.

Since the portion D serves as the equivalent short-circuit surface, the electromagnetic wave distribution in the waveguide 301 does not change regardless of the presence of the choke structure. Further, since the current flowing on the wall surface at the portion C is “zero”, even if there is some gap at a sliding portion, microwave leakage, discharge, or the like does not occur, so that the microwave can be surely propagated.

Shield spirals 305 are provided between the support rods 304 and a vacuum container 101 so that microwave leakage to the outside of the apparatus can be surely prevented.

As shown in FIG. 12, a partition member 106 is provided with a plurality of gas ejection holes 307 for ejecting a gas into the vacuum container 101 and gas flow paths 306 for conducting the gas to the plurality of gas ejection holes 307. The gas flow paths 306 are connected to a gas supply system.

In this embodiment, the single waveguide 301 is provided. However, a plurality of waveguides 301 may be arranged side by side and each dielectric plate 104 may be arranged so as to lie over the plurality of waveguides 301. The number of the slots 103 may be other than six. The number of the gas flow paths 306 may be other than seven. It may be configured that there are provided a plurality of systems each including a gas supply system, gas flow paths 306, and gas ejection holes 307, thereby supplying different gases, respectively. The thickness of each dielectric plate 104 may have a distribution depending on the distance from the slot 103. The inside of the waveguide 301 and the inside of each slot 103 are made hollow, but dielectrics may be inserted therein as described in the second embodiment. Instead of the choke structure, a shield spiral, a plate spring, or the like may be provided between the plunger 302 and the waveguide 301. The shield spirals 305 may not necessarily be provided.

### Embodiment 4

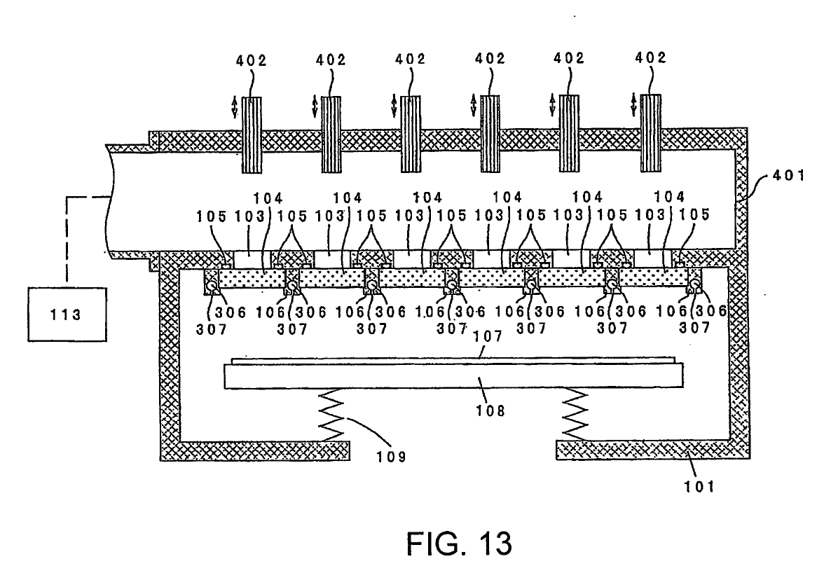

FIG. 13 is a sectional view showing the fourth embodiment among the plasma processing apparatuses of this invention. Herein, only what is different from the third embodiment will be described.

A single rectangular waveguide 401 is disposed with its E surfaces being parallel to a substrate 107. The waveguide 401 has one end forming a short-circuit surface and the other end to which a microwave supply system 113 is connected.

Wavelength adjusting rods 402 are inserted into the waveguide 401 through a plurality of holes formed in the top surface of the waveguide 401. The wavelength adjusting rods 402 are arranged at regular intervals of “λg/2”, but may be arranged at other intervals. The wavelength adjusting rods 402 are made of gold-plated copper, but may be made of aluminum, fluororesin, quartz, mullite, alumina, sapphire, yttria, aluminum nitride, silicon nitride, or the like. By vertically moving the respective wavelength adjusting rods 402 from the outside of the waveguide 401 to change the length of each rod inserted into the waveguide 401, the guide wavelength λg can be adjusted.

In this embodiment, the single waveguide 401 is provided. However, a plurality of waveguides 401 may be arranged side by side and each dielectric plate 104 may be arranged so as to lie over the plurality of waveguides 401. The inside of the waveguide 301 and the inside of each slot 103 are made hollow, but dielectrics may be inserted therein. A choke structure, a shield spiral, a plate spring, or the like may be provided between each wavelength adjusting rod 402 and the waveguide 401.

### Embodiment 5

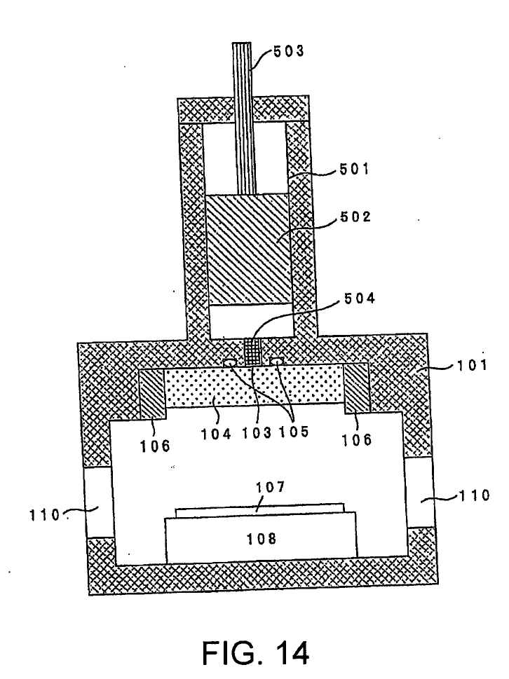

FIG. 14 is a sectional view showing the fifth embodiment among the plasma processing apparatuses of this invention. Herein, only what is different from the third embodiment will be described.

A single rectangular waveguide 501 is disposed with its E surfaces being parallel to a substrate 107. The waveguide 501 has one end forming a short-circuit surface and the other end to which a microwave supply system 113 is connected.

A plurality of slots 103 are formed at regular intervals in a surface, on the side of a stage 108, of the waveguide 501. An in-slot dielectric 504 is inserted in each slot 103 so that the intensity of a microwave emitted through the slot 103 is properly adjusted. The in-slot dielectric 504 is made of alumina, but may be made of a fluororesin, quartz, mullite, sapphire, yttria, aluminum nitride, silicon nitride, or the like or may be hollow.

A rectangular parallelepiped in-waveguide dielectric 502 smaller than the inner size of the waveguide 501 is inserted in the waveguide 501. The in-waveguide dielectric 502 is made of a fluororesin, but may be made of quartz, mullite, alumina, sapphire, yttria, aluminum nitride, silicon nitride, or the like. A support rod 503 made of, for example, a fluororesin is fixed to the in-waveguide dielectric 502. By vertically moving the in-waveguide dielectric 502 along with the support rod 503 from the outside of the waveguide 501, the guide wavelength λg can be adjusted.

According to the foregoing formula (1), it is seen that if a dielectric is provided in a hollow waveguide, the guide wavelength λg is shortened. In the case where the size of the dielectric is smaller than the inner size of the waveguide, if the dielectric is disposed at a portion where the electric field is stronger in the waveguide, the guide wavelength λg is more shortened. The electric field applied between facing H surfaces of a rectangular waveguide is the strongest on a center line of the H surfaces and is weakened as approaching E surfaces. Therefore, the guide wavelength λg becomes the shortest when the in-waveguide dielectric 502 is disposed on the center line of the H surfaces, and it becomes longer as the in-waveguide dielectric 502 is moved upward or downward from the center line. In this manner, by adjusting the guide wavelength according to the position of the in-waveguide dielectric 502, the microwave can be surely propagated without using a shield spiral, a choke structure, or the like.

In this embodiment, the single waveguide 501 is provided. However, a plurality of waveguides 501 may be arranged side by side and each dielectric plate 104 may be arranged so as to lie over the plurality of waveguides 501.

### INDUSTRIAL APPLICABILITY

A plurality of dielectric plates are provided for each of parallel-arranged waveguides, a partition member made of a conductor and grounded is disposed between the adjacent dielectric plates, and the guide wavelength of each waveguide is adjusted to an optimum value by vertically moving a plunger. Therefore, when a microwave introduced into the waveguides is propagated to the dielectric plates through slots to convert a gas, supplied into a vacuum container, into a plasma to thereby carry out plasma processing on the surface of a substrate, unintended plasma generation does not occur in any of gaps between the dielectric plates and the adjacent members. Therefore, it is applicable to a use that requires efficient generation of a stable plasma.

1. A plasma processing apparatus comprising a container in which a plasma is excited, a microwave supply system adapted to supply a microwave necessary for exciting the plasma into said container, a wave-guide path connected to said microwave supply system and formed with a plurality of slots, and a dielectric plate adapted to propagate the microwave emitted through said slots to the plasma, said plasma processing apparatus comprising
means for adjusting a wavelength of the microwave propagating in said wave-guide path, from the outside of said wave-guide path.

2. A plasma processing apparatus according to claim 1, said plasma processing apparatus being configured to move part of a conductor wall forming said wave-guide path from the outside of said wave-guide path.

3. A plasma processing apparatus according to claim 2, wherein said wave-guide path is a rectangular waveguide and said plasma processing apparatus is configured to move at least part of an E-surface (narrow wall surface) guide wall of said waveguide from the outside of said waveguide.

4. A plasma processing apparatus according to claim 1, comprising a plurality of rods inserted into said wave-guide path and being configured to move each rod from the outside of said wave-guide path.

5. A plasma processing apparatus according to claim 1, comprising a first dielectric member in said wave-guide path and being configured to move said first dielectric member from the outside of said wave-guide path.

6. A plasma processing apparatus according to claim 1, said plasma processing apparatus being configured to adjust said wavelength by changing a frequency of the microwave supplied by said microwave supply system.

7. A plasma processing apparatus comprising a container in which a plasma is excited, a gas supply system adapted to supply a gas into said container, a microwave supply system adapted to supply a microwave necessary for exciting the plasma into said container, one or more waveguides connected to said microwave supply system and formed with a plurality of slots, a plurality of dielectric plates adapted to propagate the microwave emitted through said slots to the plasma, and a stage disposed in said container for placing thereon a processing substrate, said plasma processing apparatus wherein
a plurality of said dielectric plates are provided per said waveguide and a partition member made of a conductor at least partly is provided between the adjacent dielectric plates.

8. A plasma processing apparatus according to claim 7, comprising the waveguides.

9. A plasma processing apparatus according to claim 7, wherein at least part of airtightness maintaining portions located between the inside and the outside of said container is provided between a surface, on the side of said slots, of each dielectric plate and said container.

10. A plasma processing apparatus according to claim 7, wherein a pitch between said dielectric plates in a traveling direction of the microwave propagating in said waveguide and a pitch between said slots in said traveling direction are substantially equal to each other.

11. A plasma processing apparatus according to claim 7, wherein the pitch between said slots in said traveling direction is substantially equal to a natural number times “½” of a wavelength of the microwave propagating in said waveguide.

12. A plasma processing apparatus according to claim 11, wherein the pitch between said slots in said traveling direction is substantially equal to “½” of said wavelength.

13. A plasma processing apparatus according to claim 7, wherein a second dielectric member is provided on at least part of the inside of each slot.

14. A plasma processing apparatus according to claim 13, wherein a plurality of second dielectric members having different permittivities are provided in at least part of each slot.

15. A plasma processing apparatus according to claim 7, wherein a third dielectric member is provided on at least part of the inside of said waveguide.

16. A plasma processing apparatus according to claim 7, wherein said waveguide is a rectangular waveguide and said slots are formed in an H surface (wide wall surface) of said waveguide.

17. A plasma processing apparatus according to claim 7, wherein said waveguide is a rectangular waveguide and said slots are formed in an E surface (narrow wall surface) of said waveguide.

18. A plasma processing apparatus according to claim 7, said plasma processing apparatus having a function of adjusting a wavelength of the microwave propagating in said waveguide, from the outside of said waveguide.

19. A plasma processing apparatus according to claim 18, said plasma processing apparatus being configured to move part of a guide wall of said waveguide from the outside of said waveguide.

20. A plasma processing apparatus according to claim 18, comprising a plurality of rods inserted into said waveguide and being configured to move each rod from the outside of said waveguide.

21. A plasma processing apparatus according to claim 18, comprising a first dielectric member in said waveguide and being configured to move said first dielectric member from the outside of said waveguide.

22. A plasma processing apparatus according to claim 7, wherein a thickness of each dielectric plate is set depending on a distance from said slot facing said dielectric plate.

23. A plasma processing apparatus according to claim 7, wherein a distance between said partition member and said stage is set shorter than a distance between each dielectric plate and said stage.

24. A plasma processing apparatus according to claim 7, wherein said partition member has a gas ejecting function for ejecting the gas introduced from said gas supply system into said container.

25. A plasma processing apparatus according to claim 24, wherein said partition member comprises a plurality of gas ejection holes for ejecting the gas into said container.

26. A plasma processing apparatus according to claim 7, wherein said partition member comprises a gas flow path for conducting the gas introduced from said gas supply system to said plurality of gas ejection holes.

27. A product manufacturing method of manufacturing a product by carrying out processing using the plasma processing apparatus according to claim 1.

28. A product manufacturing method of manufacturing a product by carrying out processing using the plasma processing apparatus according to claim 7.
